(19) United States
(12) Patent Application Publication
(10) Pub. No.: US 2026/0018438 A1
(43) Pub. Date: Jan. 15, 2026

(54) SYSTEM AND METHOD FOR IMPROVED OPTICAL SIGNAL DETECTION

(71) Applicant: Verity Instruments, Inc., Carrollton, TX (US)

(72) Inventor: Andrew Kueny, Carrollton, TX (US)

(21) Appl. No.: 19/261,399

(22) Filed: Jul. 7, 2025

Related U.S. Application Data
(60) Provisional application No. 63/670,232, filed on Jul. 12, 2024.

(51) Int. Cl. H01L 21/67; H01L 21/66

(52) U.S. Cl. CPC H01L 21/67253; H01L 22/26

(57) ABSTRACT

The disclosure provides an optical signal detection system with improved spectral resolution and signal-to-noise that can be used for improved monitoring of semiconductor processes. The improved spectral resolution may be associated with improved spectral discrimination where narrow portions of spectral bandwidth are individually monitored. In one example, an optical signal detection system is provided that includes: (1) an optical interface configured to receive an optical signal, (2) a narrow bandpass filter configured to transmit a portion of the received optical signal, (3) an optical etalon in series with the narrow bandpass filter, configured to further filter the received optical signal, wherein the combination of a passband of the bandpass filter and a passband of the optical etalon is configured to provide an optical bandwidth of less than 1.0 nm for the optical signal, and (4) a multipixel optical sensor configured to essentially simultaneously collect the filtered optical signal.

### CROSS-REFERENCE TO RELATED APPLICATION

This application claims the benefit of U.S. Provisional Application Ser. No. 63/670,232, filed by Andrew Kueny on Jul. 12, 2024, entitled “System and Method for Improved Optical Signal Detection”, which is commonly assigned with this application and incorporated herein by reference in its entirety.

### TECHNICAL FIELD

This disclosure relates, generally, to optical measurement systems and methods of use, and more specifically, to systems and methods for improved resolution and signal-to-noise monitoring of optical emissions from semiconductor processes.

### BACKGROUND

Optical monitoring of semiconductor processes is a well-established method for controlling processes such as etch, deposition, chemical mechanical polishing and implantation. Optical emission spectroscopy (OES) and interferometric endpoint (IEP) are two basic types of modes of operation for data collection. In OES applications light emitted from the process, typically from plasmas, is collected and analyzed to identify and track changes in atomic and molecular species which are indicative of the state or progression of the process being monitored. In IEP applications, the interference patterns of light reflected from a wafer is analyzed and used to indicate the state or progression of the process being monitored.

### SUMMARY

In one aspect, the disclosure provides an optical signal detection system. In one example, the optical signal detection system includes: (1) an optical interface configured to receive an optical signal, (2) a narrow bandpass filter configured to transmit a portion of the received optical signal, (3) an optical etalon in series with the narrow bandpass filter, configured to further filter the received optical signal, wherein the combination of a passband of the bandpass filter and a passband of the optical etalon is configured to provide an optical bandwidth of less than 1.0 nm for the optical signal, and (4) a multipixel optical sensor configured to essentially simultaneously collect the filtered optical signal.

In another aspect, a semiconductor processing control system is disclosed. In one example, the semiconductor processing control system includes: (1) a processing tool configured to perform a semiconductor manufacturing process that generates an optical signal, (2) an optical interface configured to receive the optical signal, (3) a narrow bandpass filter configured to transmit a portion of the received optical signal, (4) an optical etalon in series with the narrow bandpass filter, configured to further filter the received optical signal, wherein the combination of a passband of the bandpass filter and a passband of the optical etalon provides an optical bandwidth of less than 1.0 nm for the optical signal, and (5) a multipixel optical sensor configured to essentially simultaneously collect the filtered optical signal.

In yet another aspect, a method of controlling a semiconductor process system is disclosed. In one example, the method includes: (1) generating an optical signal within a processing chamber of a semiconductor process system, (2) receiving the optical signal at an optical interface, (3) filtering the received optical signal using a narrow bandpass filter that transmits a portion of the received optical signal, (4) further filtering the received optical signal using an optical etalon in series with the narrow bandpass filter, wherein the combination of a passband of the bandpass filter and a passband of the optical etalon provides an optical bandwidth of less than 1.0 nm for the optical signal, and (5) essentially simultaneously collecting the filter optical signal using a multipixel optical sensor.

### BRIEF DESCRIPTION OF THE DRAWINGS

Reference is now made to the following descriptions taken in conjunction with the accompanying drawings, in which:

FIG. 1 is a block diagram of a system for employing OES and/or IEP to monitor and/or control the state of a plasma or non-plasma process within a semiconductor process tool;

FIG. 2 is a plot of an optical emission spectrum with typical resolution of approximately 1 nm;

FIG. 3 is a plot of a portion of the spectrum of FIG. 2;

FIG. 4 is a plot of a portion of a spectrum indicating the presence of various emission lines that may be used for process monitoring;

FIG. 5 is a plot of a portion of a spectrum with increased resolution indicating various emission lines that may be used for process monitoring;

FIG. 6 is a schematic diagram of a proposed optical signal detection system with improved resolution and signal-to-noise characteristics;

FIG. 7 is a plot of a portion of example transmission curves for an etalon and a bandpass filter, respectively, showing the relative wavelength locations, transmission, and spectral bandwidth of each component;

FIG. 8 is a block diagram of a proposed optical signal detection system with improved resolution and signal-to-noise characteristics, and

FIG. 9 is a flow chart of a method of controlling a semiconductor process system using an optical signal detection system.

### DETAILED DESCRIPTION

In the following description, reference is made to the accompanying drawings that form a part hereof, and in which is shown by way of illustration, specific embodiments in which the invention may be practiced. These embodiments are described in sufficient detail to enable those skilled in the art to practice the invention, and it is to be understood that other embodiments may be utilized. It is also to be understood that structural, procedural and system changes may be made without departing from the spirit and scope of the present invention. The following description is, therefore, not to be taken in a limiting sense. For clarity of exposition, like features shown in the accompanying drawings are indicated with like reference numerals and similar features as shown in alternate embodiments in the drawings are indicated with similar reference numerals. Other features of the present invention will be apparent from the accompanying drawings and from the following detailed description. It is noted that, for purposes of illustrative clarity, certain elements in the drawings may not be drawn to scale.

The constant advance of semiconductor processes toward faster processes, smaller feature sizes, more complex structures, and larger wafers places great demands on process monitoring technologies. For example, higher data rates are required to accurately monitor much faster etch rates on very thin layers where changes in Angstroms (a few atomic layers) are critical such as for fin field-effect transistor (FINFET) and three-dimensional NAND (3D NAND) structures. Wider optical bandwidth, higher resolution, and greater signal-to-noise are required in many cases both for OES and IEP methodologies to aid in detecting small changes for reflectances, optical emissions, or both. Cost and packaging sizes are also under constant pressure as the process equipment becomes more complex and costly itself. These processing requirements are driving the need for improvements in the performance of optical monitoring of semiconductor processes.

Growing complexities in process chemistries along with reductions in process open areas are also driving advancements in process monitoring systems and most often require improved signal to noise and signal detection capabilities. Although improvements may be provided with better performing electronic components such as A/D convertors, power supplies and higher NEP sensors; the utility of process control information may remain inhibited. Accordingly, this disclosure provides an optical signal detection system with improved spectral resolution and signal-to-noise that can be used for improved monitoring of semiconductor processes. Herein, improved spectral resolution may be associated with improved spectral discrimination where narrow portions of spectral bandwidth are individually monitored. The disclosure includes at least one implementation of an improved optical signal detection system combining a predetermined process specific wavelength range, high optical throughput, very high wavelength resolution/discrimination, improved out-of-band light rejection, and enhanced signal-to-noise characteristics to provide an improved process control instrument.

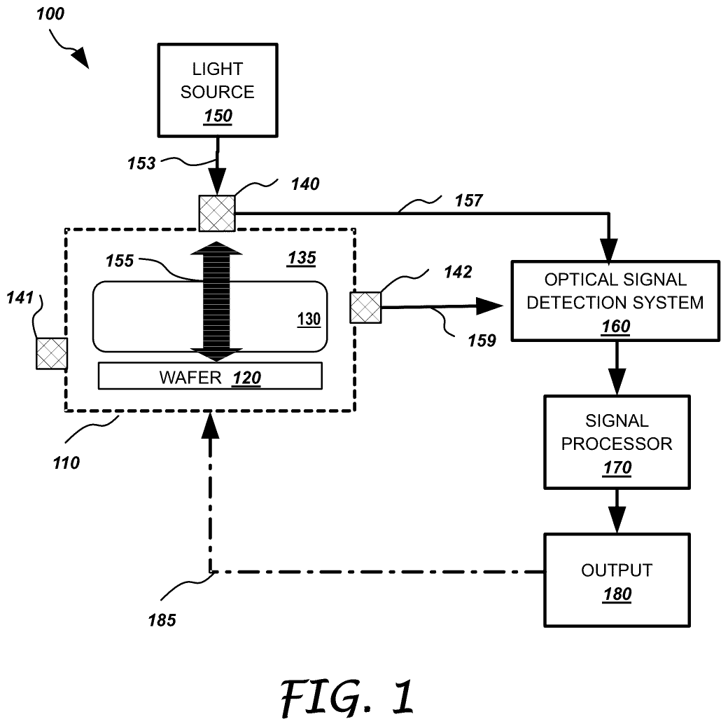

With specific regard to monitoring and evaluating the state of a semiconductor process within a process tool, FIG. 1 illustrates a block diagram of process system 100 utilizing OES and/or IEP to monitor and/or control the state of a plasma or non-plasma process within a semiconductor process tool 110. Semiconductor process tool 110, or simply process tool 110, generally encloses wafer 120 and possibly process plasma 130 in a typically, partially evacuated volume of a processing chamber 135 that may include various process gases. Process tool 110 may include one or multiple optical interfaces, or simply interfaces, 140, 141 and 142 to permit observation into the processing chamber 135 at various locations and orientations for receiving an optical signal. Interfaces 140, 141 and 142 may include multiple types of optical elements such as, but not limited to, optical filters, lenses, windows, apertures, fiber optics, etc.

For IEP applications, light source 150 may be connected with interface 140 directly or via fiber optical cable assembly 153. As shown in this configuration, interface 140 is oriented normal to the surface of wafer 120 and often centered with respect to the same. Light from light source 150 may enter the internal volume of processing chamber 135 in the form of collimated beam 155. Beam 155 upon reflection from the wafer 120 may again be received by interface 140. In common applications, interface 140 may be an optical collimator. Following receipt by interface 140, the light may be transferred via fiber optic cable assembly 157 to optical signal detection system 160 for detection and conversion to digital signals. The light can include sourced and detected light and may include, for example, the wavelength range from deep ultraviolet (DUV) to near-infrared (NIR). Wavelengths of interest may be selected from any subrange of the wavelength range. For larger substrates or where understanding of wafer non-uniformity is a concern, additional optical interfaces (not shown in FIG. 1) normally oriented with the wafer 120 may be used. The semiconductor processing tool 110 can also include additional optical interfaces positioned at different locations for other monitoring options.

For OES applications, interface 142 may be oriented to collect light emissions from plasma 130. Interface 142 may simply be a viewport or may additionally include other optics such as lenses, mirrors and optical wavelength filters. Fiber optic cable assembly 159 may direct any collected light, also referred to as an optical signal, to optical signal detection system 160 for detection and conversion to digital signals. Optical signal detection system 160 may also be directly coupled, via a free-space optical assembly, to interface 142 and/or processing tool 110 without the use of interconnecting fiber optic cable assembly 159. Multiple interfaces may be used separately or in parallel to collect OES related optical signals. For example, interface 141 may be located to collect emissions from near the surface of wafer 120 while interface 142 may be located to view the bulk of the plasma 130, as shown in FIG. 1. Although not shown, interface 141 may be coupled to optical signal detection system 160 directly or via a fiber optic cable assembly (not shown).

After detection and conversion of the received optical signals to analog electrical signals by the optical signal detection system 160, the analog electrical signals are typically amplified and digitized within a subsystem of optical signal detection system 160, and passed to signal processor 170. Signal processor 170 may be, for example, an industrial PC, PLC or other system, which employs one or more algorithms to produce output 180 such as, for example, an analog or digital control value representing the intensity of a specific wavelength or the ratio of two wavelength bands. Instead of a separate device, signal processor 170 may alternatively be integrated with optical signal detection system 160. The signal processor 170 may employ an OES algorithm that analyzes emission intensity signals at predetermined wavelength(s) and determines trend parameters that relate to the state of the process and can be used to access that state as in, for instance end point detection, etch depth, etc. For IEP applications, the signal processor 170 may employ an algorithm that analyzes wide-bandwidth portions of spectra to determine a film thickness. For example, see System and Method for In-situ Monitor and Control of Film Thickness and Trench Depth, U.S. Pat. No. 7,049,156, incorporated herein by reference. Output 180 may be transferred to process tool 110 via communication link 185 for monitoring and/or modifying the production process occurring within processing chamber 135 of the process tool 110.

The shown and described components of FIG. 1 are simplified for expedience and are commonly known. In addition to common functions, the optical signal detection system 160, the signal processor 170, or a combination of both can also be configured to identify stationary and transient optical and non-optical signals and process these signals according to the methods and/or features disclosed herein. As such, the optical signal detection system 160 or the signal processor 170 can include algorithms, processing capability, and/or logic to identify and process optical signals and temporal trends extracted therefrom. The algorithms, processing capability, and/or logic can be in the form of hardware, software, firmware, or any combination thereof. The algorithms, processing capability, and/or logic can be within one computing device or can also be distributed over multiple devices, such as the optical signal detection system 160 and the signal processor 170.

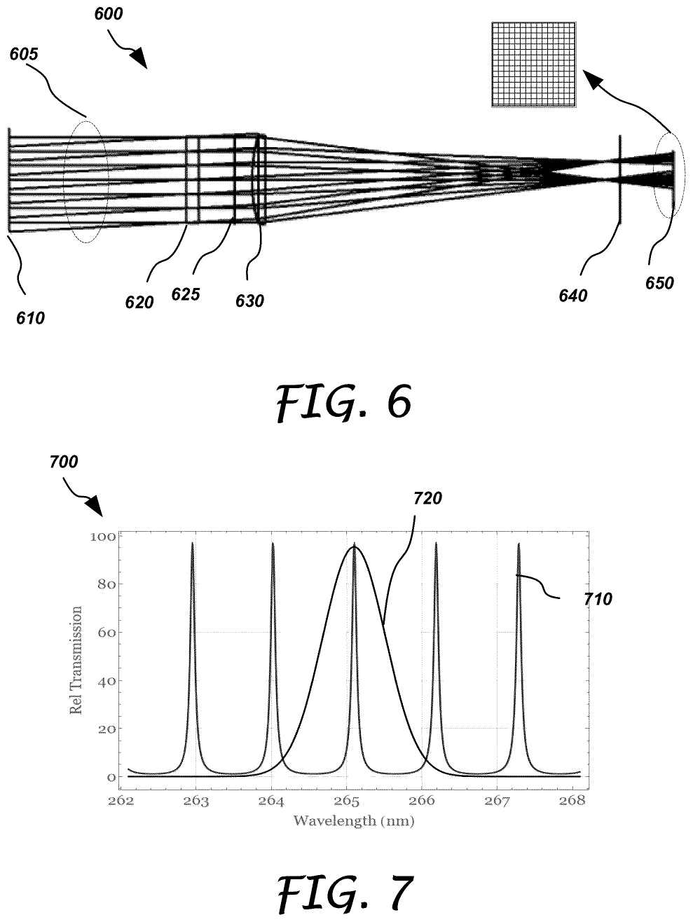

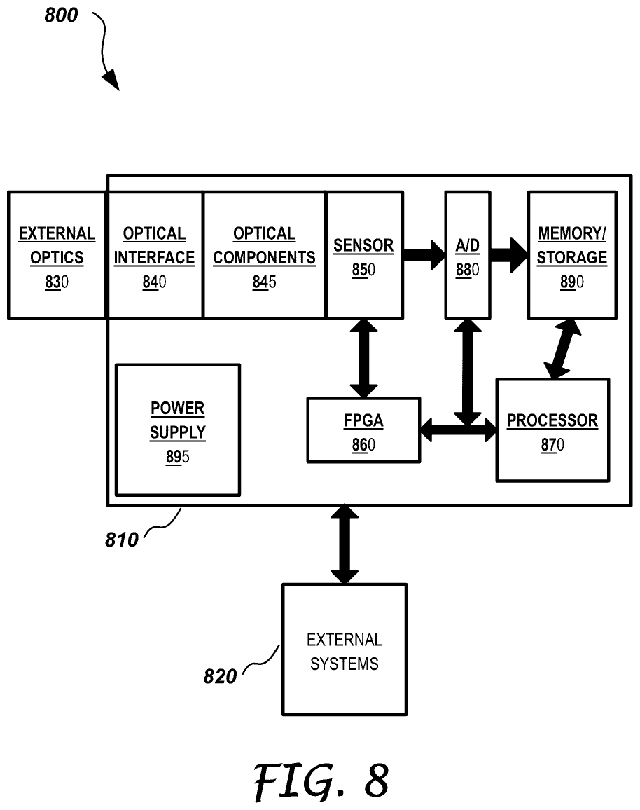

Optical signal detection system 160 can be an optical signal detection system that is configured to provide discrimination and detection of a specific spectral bandwidth associated with emissions of a desired species. Accordingly, the optical signal detection system 160 can provide/include improved spectral discrimination and signal-to-noise characteristics suitable for observing process control transitions where individual specific emissions of the desired species are present and require improved detection. For example, the optical signal detection system 160 can be an optical signal detection system, such as, optical signal detection system 600 of FIG. 6. The optical signal detection system 160 can provide an improved signal to noise ratio for a specific narrow bandwidth portion of a spectrum of interest. Such as discussed herein in association with FIG. 8, optical signal detection system 160 can include electronics in addition to the optical detection system 600 for converting the collected and filtered optical signal from analog to digital form. Instead of included with the optical signal detection system 160, the electronics may be part of the signal processor 170.

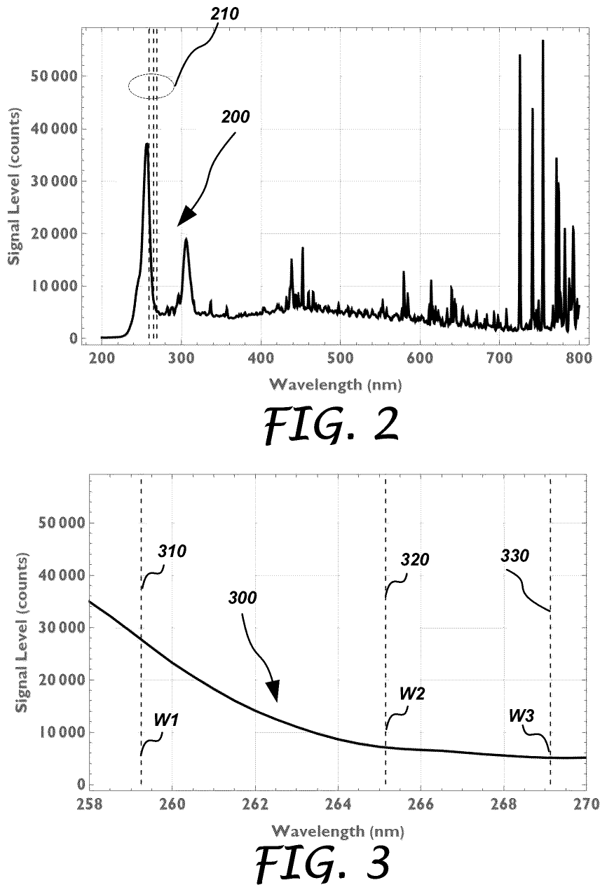

FIGS. 2 thru 5 show plots of optical emission spectra that demonstrate how the spectral resolution and signal-to-noise of emission spectra can influence the type and amount of information that is obtained and available for process control. The examples described herein are not specific to any specific spectral emission of any specific atomic or molecular species and it should be understood that similar discussion could be applicable to other atomic or molecular species when similar resolution and signal-to-noise conditions are present and/or required. The plots of FIGS. 2 thru 5 have x-axes of wavelength in nanometers and y-axes in arbitrary scales of signal counts.

FIG. 2 is a plot of an example of an optical emission spectrum 200 with typical resolution of approximately 1 nm. The optical emission spectrum 200 represents an optical signal such as received from a processing tool, such as processing tool 110. The optical emission spectrum 200 includes a combination of background signal, such as ambient light, emissions from process gases within a processing chamber, such as processing chamber 135, and emissions for monitoring. The emissions or wavelengths for monitoring are emissions that have been identified and designated for controlling a process within the processing chamber. As an example process, monitoring of emission spectra with spectral lines 210 near 250 nm are used. As shown in FIG. 2, these specific spectral emission lines 210, which provide an example of emissions to monitor, are not readily observed and the observation of the emission lines are inhibited by multiple aspects of the spectrum 200. These aspects include the presence of a large molecular spectral feature near 250 nm and limited signal-to-noise of the desired emissions due to low signal levels, relatively low spectral resolution/discrimination, and inherent low concentration and/or excitation of the species in the observed plasma.

FIG. 3 is a plot of an enlarged and localized portion 300 of the spectrum 200 of FIG. 2 near 250 nm that is essentially featureless with regards to emission lines w1, w2, and w3, which are an example of the spectral lines 210 to monitor and are respectively indicated by wavelength locations 310, 320, and 330. The most pronounced feature of spectrum 200 is the tail of the spectral feature near 250 nm that provides a large background signal at the wavelengths of interest 310, 320, 330, for the monitoring of the species of interest. This large background signal complicates the observation and detection of the species of interest at the expected wavelengths 310, 320, 330, since the large background signal has associated with it a proportionally large noise level (approx. square-root of the background signal), a comparatively much greater utilization of the dynamic range of the observing sensor, and any fluctuation/variation of the background signal may mask and degrade the observations of the expected much smaller emission signals.

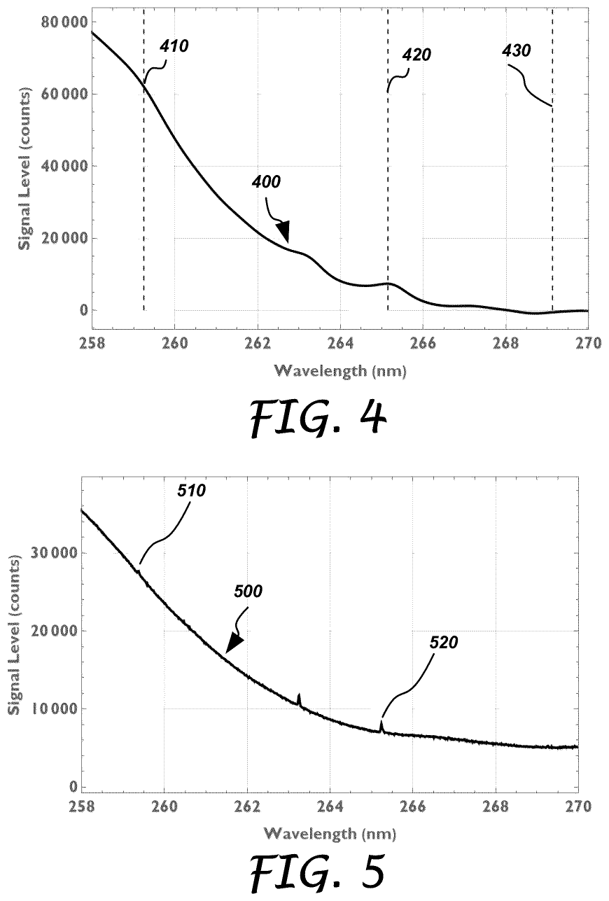

FIG. 4 is a plot of a portion of a spectrum 400 covering the same spectral range as FIG. 3 and indicating the presence of various emission lines that may be used for process monitoring of the desired species at the expected mission line wavelengths. Emission lines w1, w2, and w3 are respectively indicated by wavelength locations 410, 420, and 430 and provide differing presentations of various emission signals of interest, at the indicated wavelengths, above the large background. Emission lines 410, 420, 430, provide an example of emission lines 310, 320, and 330 of FIG. 3. Emission line w1 at location 410 is indicated by an inflection of the background signal. Emission line w2 at location 420 is indicated by a small broad peak above the background signal. Emission line w3 at location 430 is essentially not observable except as an inflection in the background signal. Although emission line w2 at wavelength location 420 is observable the relatively low spectral resolution, large background, and resultant low signal-to-noise inhibit robust control using the signal corresponding to w2. The ability to use emission lines w1 and w3 are more severely inhibited by the extremely low expression of these signals relative to the background signal.

FIG. 5 is a plot of a portion of a spectrum 500 covering the same spectral range as FIG. 3 but with significantly increased resolution indicating various emission lines that may be used for process monitoring. FIG. 5, for example, provides an example of a portion of an optical spectrum that may be incident upon the optical signal detection system 600 of FIG. 6. With increased wavelength resolution, emission line w1 at location 510 is now indicated by a small narrow peak above the background signal with signal-to-noise of approximately 1:1 or less. Similarly, emission line w2 at location 520 is indicated by a small narrow peak above the background signal with signal-to-noise of approximately 3:1 or less. The peak at 520 can be much less than one nm wide. Emission line w3 remains generally unresolved, wherein emission lines 510, 520, provide an example of emission lines 410, 420 of FIG. 4. Spectrum 500 also includes a non-denoted peak near 263 nm which is, for example, a non-monitored emission.

Although the foregoing plots have shown spectrally resolved data as from a spectrometer, it should be understood that these plots have been shown to support clear conveyance of the difficulties regarding spectral resolution/discrimination and signal-to-noise for small signals. A small signal is a signal that is difficult to observe due to, for example, a minimum Signal to Noise change or minimum amplitude difference compared to a local background signal. For example, as shown in FIGS. 2-5, the large spectral feature near 250 nm is much greater in amplitude than the features at the wavelengths of interest. For certain monitoring applications, spectrally resolved broadband data may not be required to achieve robust process control. For example, in the current exemplary case, the process monitoring condition may seek a signal transition of an intensity of an emission line from a stable higher level to a stable lower level or vice versa. This type of signal transition may simply require discrimination and detection of a specific narrow spectral bandwidth associated with one or more of the emissions of the desired species and not the comparison of emission intensities across multiple species or wider bandwidths. Each narrowband wavelength range of interest can correspond to a specific chemical constituent of an element or molecule of a semiconductor process, such as those used for dopants.

Accordingly, FIG. 6 is a schematic diagram of an example of an optical signal detection system 600 constructed according to the principles of the disclosure. Optical signal detection system 600 provides improved spectral discrimination, narrow bandwidth (high spectral resolution), high optical throughput, and signal-to-noise characteristics suitable for observing process control transitions where individual specific emissions of the desired species are present and desirable for use in process control applications. Optical signal detection system 600 includes an optical interface, represented by source plane 610, configured to receive an optical signal, generally indicated by rays 605, from source plane 610 which may define a free-space optical interface such as interfaces 140, 141, and 142 of FIG. 1. Source plane 610 may be defined with a large clear aperture (field of view), such as one with a 1″ diameter, to provide large light gathering power. Alternatively, the field of view may be restricted to a smaller diameter, such as ¼″, as limited by design of a processing tool such as processing tool 110 of FIG. 1 or to specifically restrict the field of view to a localized region of the available optical signal such as emitted from a plasma within a processing chamber, such as processing chamber 135. Alternatively, source plane 610 may be configured to attach to an optical fiber cable assembly interface including one or more optical fibers. The received optical signal may subsequently be transmitted through narrow bandpass filter 620 and etalon 625 for spectral bandwidth definition and discrimination and, for example, providing an optical bandwidth of less than 1.0 nm for the optical signal. Etalon 625 may be for example, an air-spaced etalon with a free spectral range of approximately 1 nm or less, a finesse of 5 or 10 or more, a resonance/peak bandwidth of less than 0.5 nm or less than 0.1 nm, and a peak transmission of approximately 70%. Etalon 625 may be, for example, provided by Light Machinery of Canada. Bandpass filter 620 may be useful in system 600 for suppression of sidebands of etalon 625. Narrow bandpass filter 620 may have a bandwidth of approximately 10 nm or less where the center wavelength of the etalon (or one of the resonances of the etalon) and the bandpass filter are roughly equivalent. Bandpass filter 620 may be available, for example, from Edmund Optics. The optical signal detection system 600 also includes a lens 630, a field stop 640, and a sensor 650.

FIG. 7 is a plot 700 of a portion of the transmission curves 710 and 720 for a an etalon and a bandpass filter, such as etalon 625 and bandpass filter 620, respectively showing the relative wavelength locations, transmission, and spectral bandwidth of each component. One or more of the bandpass filter 620 or the etalon 625 can be tunable or exchangeable for selection of different wavelengths. As such, different signals of interest can be monitored and processed to control, for example, a semiconductor process within a chamber. Signal processor 170, for example, can be configured to process a received digital signal corresponding to a received, collected, converted, and filtered optical signal and generate controls for a semiconductor process. Signal processor 170 or another processor such as described in association with FIG. 8 may also be used to automate control or exchange of elements of optical signal detection system 600 such as temperature control of the resonance center wavelength of etalon 625, substitution of bandpass filter 620, and control of signal acquisition by sensor 650.

After wavelength discrimination by the bandpass filter 620 and etalon 625 combination, the optical signal may be passed through a lens 630 to provide reimaging of the source plane via field stop 640. Lens 630 may be, for example, a 25 mm diameter fused silica lens with 100 mm focal length and a 10 mm clear aperture. Lens 630 may also include antireflective or bandwidth control coatings that further support wavelength discrimination and the rejection of undesired wavelengths. A suitable bandwidth control coating on lens 630 may supplement or replace the function of bandpass filter 620. After aperturing via field stop 640, the optical signal may be collected upon the active surface of multipixel sensor 650. Sensor 650 may be, for example, the S16101 back-illuminated active pixel sensor provided by Hamamatsu Photonics of Hamamatsu City, Japan. Sensor 650 may include a two-dimensional array of pixels, such as 1280×1024 pixels for the S16101, or less (i.e. 100×100) or more (i.e. 2048×2048) pixels based upon, for example, a desired area of detection or an expected signal-to-noise response. Optical signal detection system 600 as described may provide a nominal bandwidth of approximately 0.3 nm or less and a maximum signal-to-noise ratio of 150,000. This is achieved by simultaneous optical signal collection and averaging over the approximately 1.3 million pixels (considering the S16101 sensor option) of multipixel sensor 650. Each of the pixels of sensor 650 may receive the same or essentially the same optical signal.

The physical size of the components of the optical signal detection system 600 are such to allow a large amount of light to be sensed by sensor 650. The diameter of the different components of the optical signal detection system 600 can be relative depending on, for example, which of the components is the limiting component regarding the amount of light passing therethrough. The diameter of the lens 630 and/or of another one of the components of the optical detection system 600, such as aperture 640, can be one inch. The components of the optical signal detection system 600, such as elements 610, 620, 625, 630, and 640, can have or provide a field of view of, for example, ¼ inch to 1 inch. The field of view can be based on the physical size of sensor 650 to ensure a sufficient optical signal is received by the sensor 650 for processing. The separated rays at sensor 650 represent different field angles at source 610.

FIG. 8 is block diagram of an example of an optical signal detection system 800 constructed according to the principles of the disclosure. Optical signal detection system 800 has improved resolution and signal-to-noise characteristics per the disclosure. Optical signal detection system 800 may incorporate the system, features, and methods disclosed herein to the advantage of measurement, characterization, analysis, and processing of optical signals from semiconductor processes and may be associated with optical signal detection system 160 and signal processor 170 of FIG. 1 as well as optical signal detection system 600 of FIG. 6.

Optical signal detection system 800 may be enclosed with a housing 810 and may include an optical interface 840 for receiving optical signals from external optics 830, such as interfaces 141 and 142 of FIG. 1 or via fiber optic cable assemblies 157 or 159, and may, following integration and conversion, send data, such as output 180 of FIG. 1, to external systems 820, which may also be used to control optical signal detection system 800 by, for example, selecting a mode of operation or controlling integration timing as defined herein.

Optical interface 840 may be a subminiature assembly (SMA) or ferrule connector (FC) fiber optic connector or other opto-mechanical interface such as a free-space interface. Further optical components 845 such as slits, lenses, filters, etalons, and gratings may act to form, guide, discriminate, and chromatically separate the received optical signals and direct them to multipixel sensor 850 for integration and conversion.

Low-level functions of multipixel sensor 850 may be controlled by elements such as FPGA 860 and processor 870. Following optical to electrical conversion, analog signals may be directed to A/D convertor 880 and converted from electrical analog signals to electrical digital signals which may then be stored in memory 890 for immediate or later use and transmission, such as to external systems 820 (c.f., signal processor 170 of FIG. 1). Although certain interfaces and relationships are indicated by arrows, not all interactions and control relations are indicated in FIG. 8. Spectral data may be, for example, collected, stored and/or acted upon within/by one or multiple of memory/storage 890, FPGA 860, processor 870 and/or external systems 820. Memory/storage 890, FPGA 860, processor 870, and/or external systems 820 provide examples wherein the processing capability, logic, and/or operating instructions corresponding to algorithms for processing optical signals as disclosed herein can be stored. Optical signal detection system 800 also includes a power supply 895, which can be a conventional AC or DC power supply.

As noted above, optical signal detection system 800 may be associated with optical signal detection system 160. Optical signal detection system 800 may also correspond to the optical signal detection system 600 of FIG. 6. For example, optical interface 840 can correspond to source plane 610, optical components 845 can correspond to bandpass filter 620, etalon 625, and lens 630, and sensor 850 can correspond to sensor 650. A combination of one or more of the A/D 880, memory/storage 890, FPGA 860, processor 870, or external systems 820 can correspond to electronics for analog to digital processing.

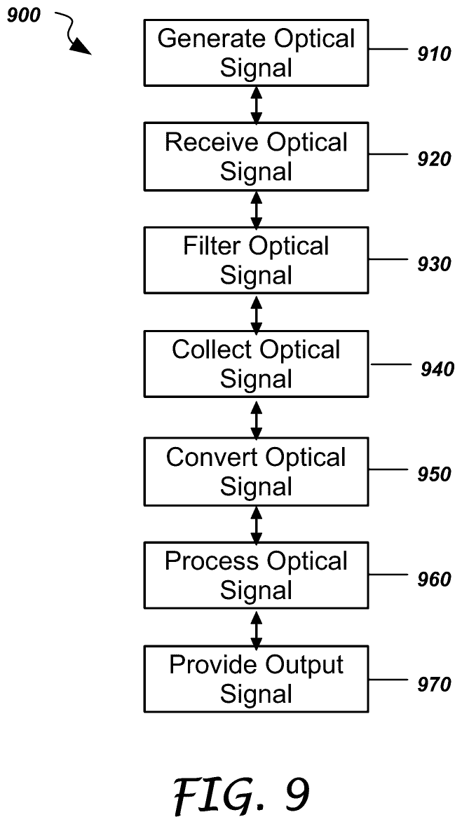

FIG. 9 is a flow chart of an example method 900 of controlling a semiconductor process system using an optical signal detection system such as described herein. Method 900 starts with step 910 wherein an optical signal is generated. The optical signal may be generated, for example, from a plasma such as plasma 130 within chamber 135 of FIG. 1. The generated optical signal may include emissions from species of interest for controlling the semiconductor process occurring within chamber 135. Next, in step 920, the optical signal may be received via an optical interface such as interface 142 of FIG. 1, source plane 610 of FIG. 6, or external optics 830 of FIG. 8. Subsequently, a received optical signal may be filtered in step 930 via filters and etalons such as described in association with FIG. 6 which transmit a predetermined portion of the bandwidth of the received optical signal. Next, during step 940, the filtered optical signal may be collected essentially simultaneously via illumination upon the active pixels of a multipixel sensor such as sensor 650 of FIG. 6. Essentially simultaneous collection may include a predetermination or predefining of timing, gating, and integration times for the multipixel sensor to maintain temporal correlation between the individual pixels of the multipixel sensor and the temporal correlation of the signals derived therefrom. Integration times, for example, may be defined to be sufficiently long to utilize the dynamic range of the pixels, sensor and associated conversion and processing systems as well as sufficiently short to maintain sufficient time resolution to be able to detect changes in the derived signals. These integration times may range from less than a second to multiple minutes. Certain individual pixels of a multipixel sensor may also not be illuminated to provide a reference or background signal for other signal derived from illuminated pixels.

In step 950, the collected optical signal may be then converted from an analog to digital form using, for example, an A/D convertor connected with a multi-pixel sensor, such as convertor 880 of FIG. 8. Following conversion, in step 960, the converted, collected, and filtered optical signal may be further processed to achieve a desired signal-to-noise level, such as 10,000:1 or greater, or to otherwise provide an output signal useful for control of the observed process. All or portions of the signals received from the plurality of pixels of the multipixel sensor may be processed individually or in combination. Processing may be performed, for example, by signal processor 170 of FIG. 1 or by FPGA 860 or processor 870 of FIG. 8. At the end of method 900, in step 970, an output signal, such as output 180 of FIG. 1, may be provided by a subsystem, such as signal processor 170 of FIG. 1 or by FPGA 860 or processor 870 of FIG. 8, to a secondary system, such as a semiconductor processing system controller, to direct control of the process from which originates the original optical signal.

Portions of disclosed embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floptical disks; and hardware devices that are specially configured to store and execute program code, such as ROM and RAM devices. Examples of program code include both machine code, such as produced by a compiler, and files containing higher level code that may be executed by the computer using an interpreter. Configured or configured to means, for example, designed, constructed, or programmed, with the necessary logic, algorithms, processing instructions, and/or features for performing a task or tasks.

The changes described above, and others, may be made in the optical measurement systems and subsystems described herein without departing from the scope hereof. For example, although certain examples are described in association with semiconductor wafer processing equipment, it may be understood that the optical measurement systems described herein may be adapted to other types of processing equipment such as roll-to-roll thin film processing, solar cell fabrication or any application where high precision optical measurement may be required. Furthermore, although certain embodiments discussed herein describe the use of a single light analyzing device, it should be understood that multiple light analyzing devices with known relative sensitivity may be utilized. Furthermore, although the term “wafer” has been used herein when describing aspects of the current invention, it should be understood that other types of workpieces such as quartz plates, phase shift masks, LED substrates and other non-semiconductor processing related substrates and workpieces including solid, gaseous and liquid workpieces may be used.

The exemplary embodiments described herein were selected and described in order to best explain the principles of the invention and the practical application, and to enable others of ordinary skill in the art to understand the invention for various embodiments with various modifications as are suited to the particular use contemplated. The particular embodiments described herein are in no way intended to limit the scope of the present invention as it may be practiced in a variety of variations and environments without departing from the scope and intent of the invention. Thus, the present invention is not intended to be limited to the embodiment shown, but is to be accorded the widest scope consistent with the principles and features described herein.

The flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems which perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As will be appreciated by one of skill in the art, the present invention may be embodied as a method, system, or computer program product. Accordingly, the present invention may take the form of an entirely hardware embodiment, an entirely software embodiment (including firmware, resident software, micro-code, etc.) or an embodiment combining software and hardware aspects all generally referred to herein as a “circuit” or “module.” Furthermore, the present invention may take the form of a computer program product on a computer-usable storage medium having computer-usable program code embodied in the medium.

Various aspects of the disclosure can be claimed including the apparatuses, systems, and methods disclosed herein. Aspects disclosed herein and noted in the Summary include:
A. An optical signal detection system that includes: (1) an optical interface configured to receive an optical signal, (2) a narrow bandpass filter configured to transmit a portion of the received optical signal, (3) an optical etalon in series with the narrow bandpass filter, configured to further filter the received optical signal, wherein the combination of a passband of the bandpass filter and a passband of the optical etalon is configured to provide an optical bandwidth of less than 1.0 nm for the optical signal, and (4) a multipixel optical sensor configured to essentially simultaneously collect the filtered optical signal.
B. A semiconductor processing control system that includes: (1) a processing tool configured to perform a semiconductor manufacturing process that generates an optical signal, (2) an optical interface configured to receive the optical signal, (3) a narrow bandpass filter configured to transmit a portion of the received optical signal, (4) an optical etalon in series with the narrow bandpass filter, configured to further filter the received optical signal, wherein the combination of a passband of the bandpass filter and a passband of the optical etalon provides an optical bandwidth of less than 1.0 nm for the optical signal, and (5) a multipixel optical sensor configured to essentially simultaneously collect the filtered optical signal.
C. A method of controlling a semiconductor process system that includes: (1) generating an optical signal within a processing chamber of a semiconductor process system, (2) receiving the optical signal at an optical interface, (3) filtering the received optical signal using a narrow bandpass filter that transmits a portion of the received optical signal, (4) further filtering the received optical signal using an optical etalon in series with the narrow bandpass filter, wherein the combination of a passband of the bandpass filter and a passband of the optical etalon provides an optical bandwidth of less than 1.0 nm for the optical signal, and (5) essentially simultaneously collecting the filter optical signal using a multipixel optical sensor.

Each of aspects A, B, and C can have one or more of the following additional elements in combination: Element 1: wherein the optical interface comprises at least one of an optical fiber interface and a free-space interface. Element 2: wherein the bandpass filter has an optical passband width of 10 nm or less. Element 3: wherein the etalon has a free spectral range of 1 nm or less. Element 4: further comprising electronics for converting the collected and filtered optical signal from analog to digital form. Element 5: further comprising a processor for processing the converted, collected, and filtered optical signal to create an output signal. Element 6: wherein the output signal is provided to a secondary system for use as a control signal for a semiconductor process from which originates the optical signal. Element 7: wherein the output signal is processed to achieve a signal to noise ratio of 10,000 or greater. Element 8:wherein a field of view of one or more of the optical interface, the narrow bandpass filter, or the optical etalon is within a range of ¼ inch to one inch in diameter. Element 9: wherein the optical interface comprises at least one of an optical fiber interface and a free-space interface. Element 10: wherein the narrow bandpass filter has an optical passband width of 10 nm or less. Element 11: wherein the optical etalon has a free spectral range of 1 nm or less. Element 12: further comprising electronics for converting the collected and filtered optical signal from analog to digital form. Element 13: further comprising a processor for processing the converted, collected, and filtered optical signal to create an output signal. Element 14: wherein the output signal is provided to the processing tool for use as a control signal for the semiconductor manufacturing process. Element 15: wherein the output signal is processed to achieve a signal to noise ratio of 10,000 or greater. Element 16:wherein a field of view of one or more of the optical interface, the narrow bandpass filter, or the optical etalon is within a range of ¼ inch to one inch in diameter. Element 17: further comprising converting the collected and filtered optical signal from analog to digital form, processing the converted, collected, and filtered optical signal to create an output signal and providing the output signal to the semiconductor process system for use as a control signal for a process from which originates the optical signal.

What is claimed is:

1. An optical signal detection system, comprising:
an optical interface configured to receive an optical signal;
a narrow bandpass filter configured to transmit a portion of the received optical signal;
an optical etalon in series with the narrow bandpass filter, configured to further filter the received optical signal, wherein the combination of a passband of the bandpass filter and a passband of the optical etalon is configured to provide an optical bandwidth of less than 1.0 nm for the optical signal; and
a multipixel optical sensor configured to essentially simultaneously collect the filtered optical signal.

2. The optical signal detection system as recited in claim 1, wherein the optical interface comprises at least one of an optical fiber interface and a free-space interface.

3. The optical signal detection system as recited in claim 1, wherein the bandpass filter has an optical passband width of 10 nm or less.

4. The optical signal detection system as recited in claim 1, wherein the etalon has a free spectral range of 1 nm or less.

5. The optical signal detection system as recited in claim 1, further comprising electronics for converting the collected and filtered optical signal from analog to digital form.

6. The optical signal detection system as recited in claim 5, further comprising a processor for processing the converted, collected, and filtered optical signal to create an output signal.

7. The optical signal detection system as recited in claim 6, wherein the output signal is provided to a secondary system for use as a control signal for a semiconductor process from which originates the optical signal.

8. The optical signal detection system as recited in claim 6, wherein the output signal is processed to achieve a signal to noise ratio of 10,000 or greater.

9. The optical signal detection system as recited in claim 1, wherein a field of view of one or more of the optical interface, the narrow bandpass filter, or the optical etalon is within a range of ¼ inch to one inch in diameter.

10. A semiconductor processing control system, comprising:
a processing tool configured to perform a semiconductor manufacturing process that generates an optical signal;
an optical interface configured to receive the optical signal;
a narrow bandpass filter configured to transmit a portion of the received optical signal;
an optical etalon in series with the narrow bandpass filter, configured to further filter the received optical signal, wherein the combination of a passband of the bandpass filter and a passband of the optical etalon provides an optical bandwidth of less than 1.0 nm for the optical signal; and
a multipixel optical sensor configured to essentially simultaneously collect the filtered optical signal.

11. The semiconductor processing control system as recited in claim 10, wherein the optical interface comprises at least one of an optical fiber interface and a free-space interface.

12. The semiconductor processing control system as recited in claim 10, wherein the narrow bandpass filter has an optical passband width of 10 nm or less.

13. The semiconductor processing control system as recited in claim 10, wherein the optical etalon has a free spectral range of 1 nm or less.

14. The semiconductor processing control system as recited in claim 10, further comprising electronics for converting the collected and filtered optical signal from analog to digital form.

15. The semiconductor processing control system as recited in claim 14, further comprising a processor for processing the converted, collected, and filtered optical signal to create an output signal.

16. The semiconductor processing control system as recited in claim 15, wherein the output signal is provided to the processing tool for use as a control signal for the semiconductor manufacturing process.

17. The semiconductor processing control system as recited in claim 15, wherein the output signal is processed to achieve a signal to noise ratio of 10,000 or greater.

18. The semiconductor processing control system as recited in claim 10, wherein a field of view of one or more of the optical interface, the narrow bandpass filter, or the optical etalon is within a range of ¼ inch to one inch in diameter.

19. A method of controlling a semiconductor process system comprising:
generating an optical signal within a processing chamber of a semiconductor process system;
receiving the optical signal at an optical interface;
filtering the received optical signal using a narrow bandpass filter that transmits a portion of the received optical signal;
further filtering the received optical signal using an optical etalon in series with the narrow bandpass filter, wherein the combination of a passband of the bandpass filter and a passband of the optical etalon provides an optical bandwidth of less than 1.0 nm for the optical signal; and
essentially simultaneously collecting the filter optical signal using a multipixel optical sensor.

20. The method of controlling a semiconductor process system as recited in claim 19, further comprising:
converting the collected and filtered optical signal from analog to digital form;
processing the converted, collected, and filtered optical signal to create an output signal; and
providing the output signal to the semiconductor process system for use as a control signal for a process from which originates the optical signal.
